(19) United States
(12) Patent Application Publication
(10) Pub. No.: US 2015/0331448 A1
(43) Pub. Date: Nov. 19, 2015

(54) BUILT-IN RETRACTABLE HANGER FOR MOBILE DEVICES

(71) Applicants: Cuong H. Truong, Cary, NC (US); Dylan Le Truong, Cary, NC (US)

(72) Inventors: Cuong H. Truong, Cary, NC (US); Dylan Le Truong, Cary, NC (US)

(21) Appl. No.: 14/277,660

(22) Filed: May 14, 2014

(51) Int. Cl. G06F 1/16; A47G 1/16; H04M 1/04; H05K 5/02

(52) U.S. Cl. CPC G06F 1/166; H05K 5/0226; A47G 1/1666; H05K 5/023; G06F 1/1616; G06F 1/1626; H04M 1/04; G06F 1/1637

(57) ABSTRACT

A built-in retractable hanger for mobile devices is provided. In an implementation, a cord is extendible and retractable within a hinge of a mobile device. A biasing member, such as one or more springs, provides tension on the cord for automatic retraction. The cord can be pulled into a hanger loop for suspending the mobile device for hands-free use in an airplane, train, or car. The retractable hanger can also be included in a protective case for a mobile device. A front cover of the mobile device or protective case can flip around to become a folding stand for selecting a viewing angle of the mobile device when suspended for hands-free use. When the mobile device is taken down from a hanging point, the retractable hanger reconceals itself in the mobile device or protective case.

### BACKGROUND

Most mobile and portable electronic devices are not travel-friendly for hands-free use on an airplane or vehicle. Placing a tablet or other mobile device on a lap or a tray table can be cumbersome and risky. When users want to use a mobile device on an airplane, without holding the device in their hands the entire time, the extra accessories needed for making a stable mount are awkward to carry and troublesome to use.

Adjustable hands-free mounting apparatuses for tablet personal computers, and other mounting schemes, have been attempted as described in references such as U.S. Pat. No. 8,474,778 to Jacobs, U.S. Pre-grant Publication No. 20100258602 to Amin, and U.S. Pat. No. 6,119,999 to Fleishman. But these systems use cumbersome straps, suction cups, and the like.

An easy, lightweight, and built-in mechanism for hands-free use of mobile devices in certain environments would enable full use of mobile devices while traveling, without carrying extra accessories.

### BRIEF DESCRIPTION OF THE DRAWINGS

FIG. 1 is a diagram of an example built-in retractable hanger for a mobile device or for a protective case for a mobile device.

FIG. 2 is a diagram of the example built-in retractable hanger for a mobile device or for a protective case for a mobile device during suspension from an airline tray release handle on a seatback.

FIG. 3 is a diagram of the example built-in retractable hanger for a mobile device or for a protective case for a mobile device during suspension from an airline tray release handle on a seatback when the airplane tray is down.

FIG. 4 is a diagram of multiple instances of the example built-in retractable hanger for a mobile device or for a protective case for a mobile device during suspension from airline tray release handles when the airplane trays are up and down.

FIG. 5 is a diagram of example built-in retractable hangers for a hinged mobile device and for an unhinged mobile device.

FIG. 6 is a diagram of an example built-in retractable hanger for a mobile device or for a protective case for a mobile device including an extra biasing spring to absorb shocks and jarring motions.

FIG. 7 is a diagram of an example built-in retractable hanger for a mobile device or for a protective case for a mobile device including an elastic biasing member.

FIG. 8 is a diagram of an example built-in retractable hanger for a mobile device or for a protective case for a mobile device including a spiral torsion spring biasing member.

FIG. 9 is a diagram of example spring configurations for cord retraction, including springs attached at each end of a metal cord to provide cord tension, and a central spring attached on each end to a cord loop, with the cord guided around end pulleys to provide cord tension to the cord loop.

FIG. 10 is a diagram of an example built-in retractable hanger for a protective case for a mobile device.

FIG. 11 is a diagram of example built-in retractable hangers for a mobile device or for a protective case for the mobile device concealed within two different types of example hinges.

FIG. 12 is a diagram of an example front cover of a mobile device or for a protective cover for a mobile device that flips to a rear position and folds to become a stand for selecting a viewing angle of the mobile device when the mobile device is suspended for hands-free use.

FIG. 13 is a diagram of a front cover flipped to become a back support member at different viewing angles, including horizontal ribs and a magnet and metal strip system to secure an edge of the front cover at various viewing angles.

FIG. 14 is a diagram of an example mobile device suspended for hands-free use at a flat viewing angle and at a tilted viewing angle selected by a folding stand at the rear of the mobile device.

FIG. 15 is a diagram of an anchoring accessory for providing a temporary hanging point by wrapping around a fixture.

FIG. 16 is diagram of an example mobile device suspended for hands-free use by the anchoring accessory and temporary hanging point of FIG. 15.

FIG. 17 is a flow diagram of an example method of suspending a mobile device for hands-free use.

### DETAILED DESCRIPTION

Overview

This disclosure describes built-in retractable hangers for mobile devices. An example system provides a mechanism for suspending a given mobile device from a hook or other hanging point. A suspended mobile device becomes a hands-free display or user interface. The hands-free display may be used as a viewing screen for movies or TV, or as a computer monitor or tablet surface. “Hands-free” does not prevent the hanging display from being a touchscreen, multitouch surface, or other user interface, rather, “hands-free” just means that the user does not have to hold the device to support it. The example system is built into the mobile device or into a protective case for the mobile device, and retracts when not in use to become unnoticeable or invisible in the device or case.

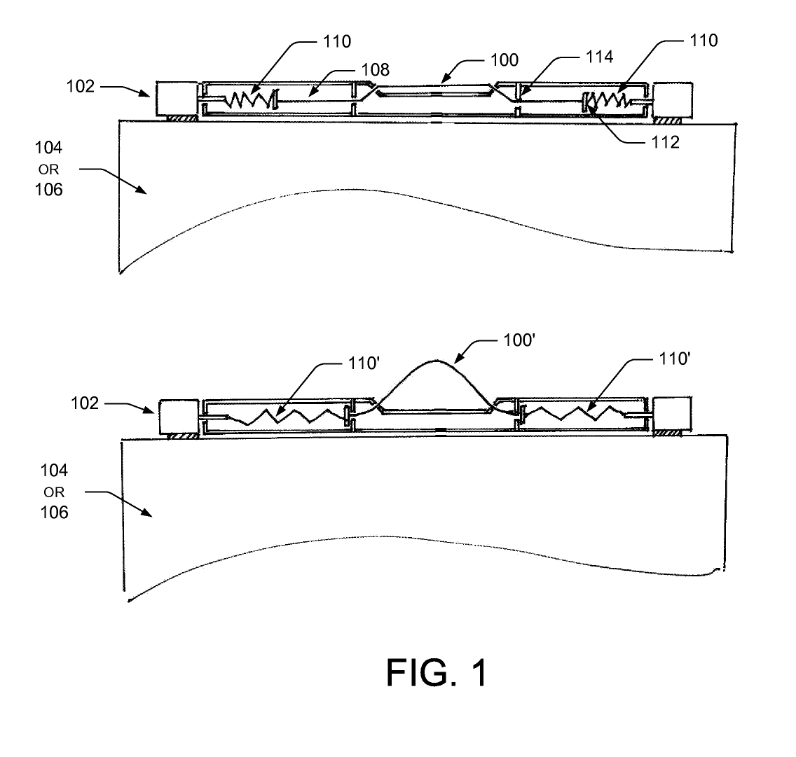

FIG. 1 shows an example implementation of a built-in retractable hanger 100, concealed within a hinge 102 of a mobile device 104, or within a protective case 106 for a mobile device 104. In an implementation, a strong cable, such as a strong polymer string, or a metal cord 108 that also forms the retractable hanger 100, is maintained under tension for retraction by one or more biasing members. A biasing member may be one or more springs 110, such as a compressible/expandable folded spring, or coil (helical) springs 110. More biasing members are described further below. The user may extend the retractable hanger 100 for use by reaching into an indent or an opening in the hinge 102, and pulling on the metal cord 108, for example. The user's pull forms an extended hanger loop 100′ of the metal cord 108, and in doing so, expands the one or more springs 110′. A moving stop 112 attached in one or more places to the metal cord 108 or spring 110 may contact a fixed stop 114 attached to the hinge 102, device 104, or case 106 to limit the ultimate extension of the extended hanger loop 100′.

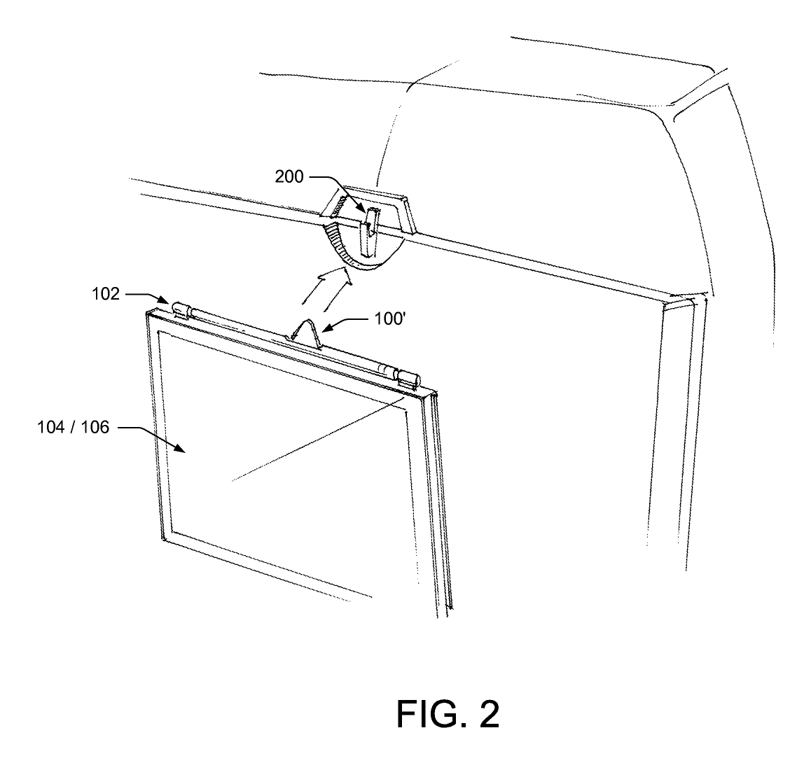

As shown in FIG. 2, the extended hanger loop 100′ can be hung on a hook or other hanging point 200. On an airplane (train, car, etc.) the seatback of a seat in front of the user may have a hook, or a tray handle with a hook or other hanging point 200. Often a tray release handle can be used as the hanging point 200 even without an explicit hook. The user places the extended hanger loop 100′ over the hanging point 200, and the case 106, tablet, or other mobile device 104 is quickly suspended for hands-free use as a display, touchscreen, or user interface.

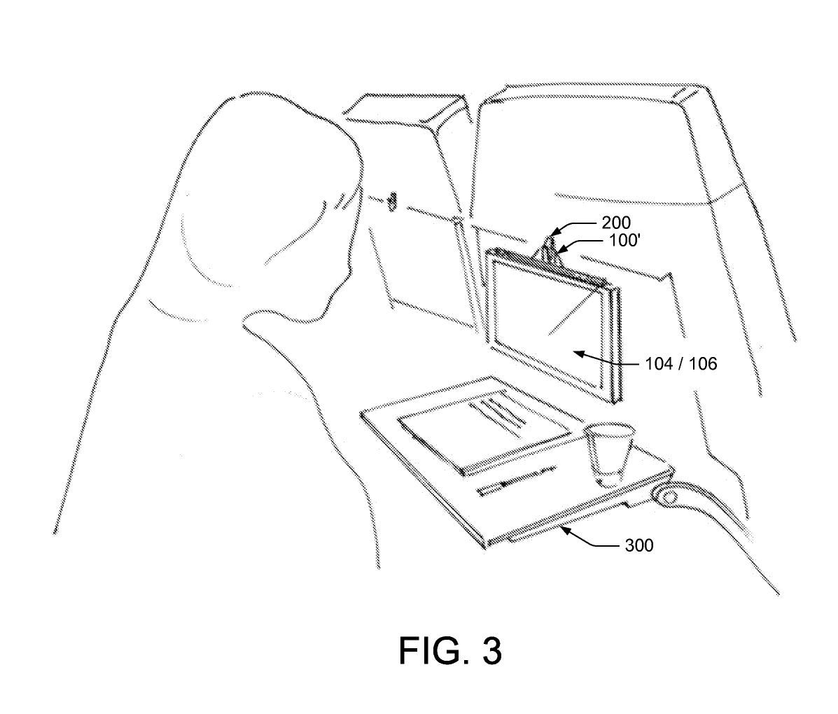

In FIG. 3, it is worth noting that the built-in retractable hanger 100 for mobile devices 104 provides an advantage over conventional mounting means in that the extended hanger loop 100′ allows the device 104 or case 106 to be suspended whether a personal airplane tray 300 is in the “up” or “down” position. Moreover, such a tray 300 can be moved up or down, from one position to the other, without having to undo and redo conventional straps or suction cups.

Sometimes the hanging point 200 has a geometry that allows the user to place the retracted metal cord 108 of the retractable hanger 100 directly over the hanging point 200, and the hanging point 200 catches the metal cord 108 and extends the hanger loop 100′ without the user having to reach into an indent to pull out the metal cord 108 to become the extended hanger loop 100′.

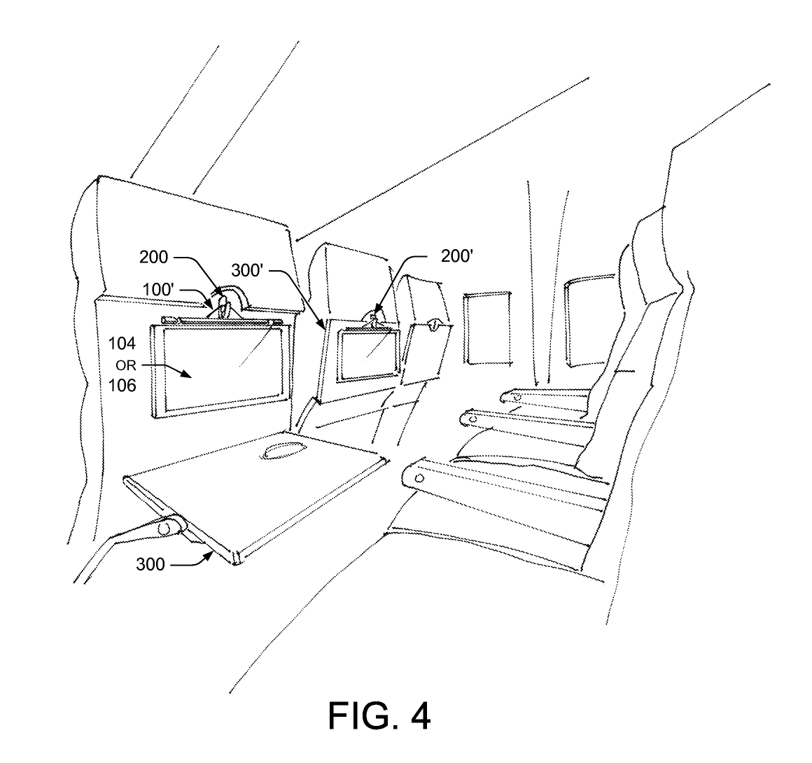

FIG. 4 shows a row of airline seating in which instances of the built-in retractable hanger 100 are in use on tray release handles as hanging points 200 & 200′, whether a given tray 300 is in use in the down position, or the given tray 300′ is put away in the up position.

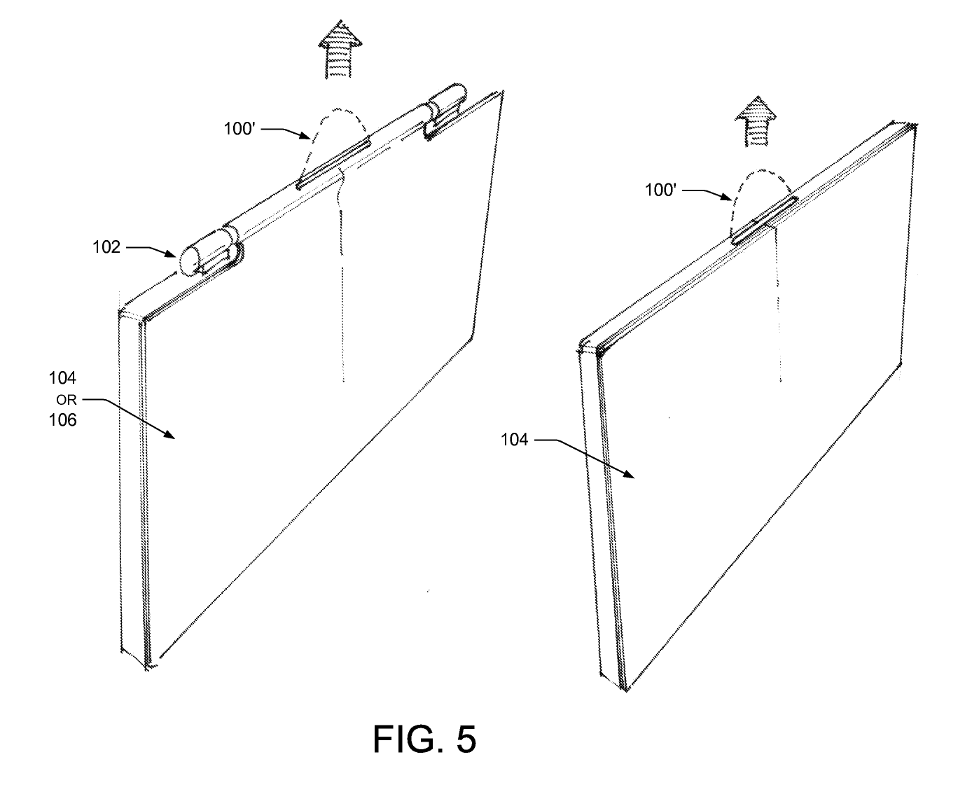

FIG. 5 shows a view of the example implementation of FIG. 1, in which the retractable hanger 100 (and extended hanger loop 100′) is built into the hinge 102 of a mobile device 104 or a protective case 106. The retractable hanger 100 (and extended hanger loop 100′) may also be built into a device 104 (or a case 106) without a hinge 102. A personal computer, laptop, tablet, all-in-one (AIO), display, phone, or other mobile device may have a retractable hanger 100 built into one or more sides of the device 104. The device 104 may be of relatively large size, such as a 12 inch or a 13 inch display, for example. When built into two sides of the device 104, the retractable hanger 100 allows the device 104 to be suspended in both portrait and landscape orientations. When not in use, the metal cord 108 of the retractable hanger 100 retracts into an indent, opening, or against the side of the device 104.

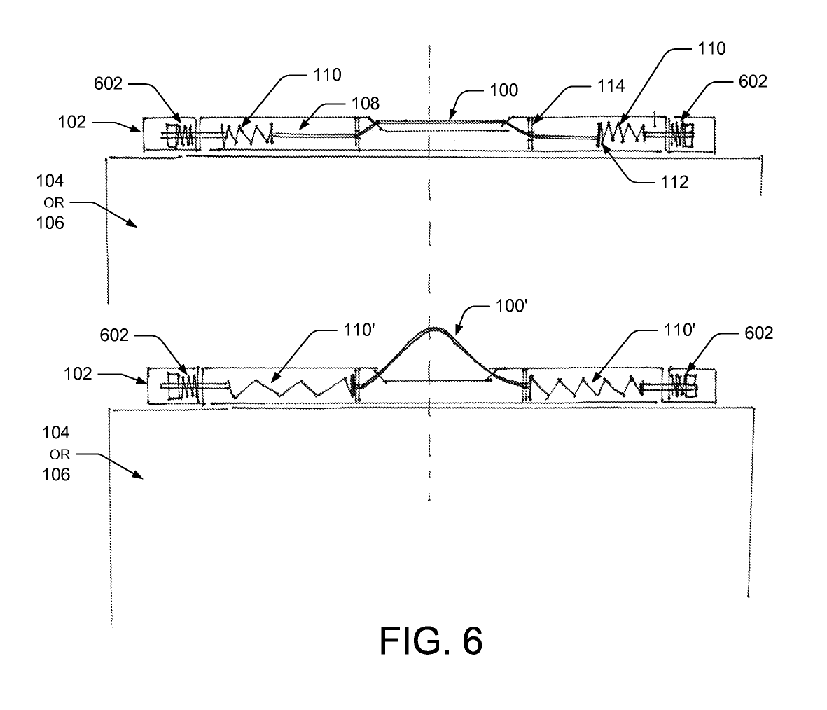

FIG. 6 shows another example implementation of the built-in retractable hanger 100, concealed within a hinge 102 of a mobile device 104 or protective case 106 for the mobile device 104. The strong cable, such as a strong polymer string, or metal cord 108 that also forms the retractable hanger 100, is retracted by one or more springs 110, such as compressible/expandable folded springs or coil springs 110, as in FIG. 1. As in FIG. 1, the user (or an inserted hanging point 200) may extend the retractable hanger 100 for use by reaching into an indent in the hinge 102, and pulling on the metal cord 108. The pull forms the extended hanger loop 100′ of the metal cord 108, and in doing so, expands the one or more springs 110′. The moving stop 112 attached in one or more places to the metal cord 108 contacts a fixed stop 114 attached to the hinge 102, device 104, or case 106 to limit the ultimate extension of the extended hanger loop 100′. In FIG. 6, an extra spring 602 or cushion may be added to provide extra damping, cushioning, or shock absorption between the hanging point 200 and the device 104 (or case 106), via the extended hanger loop 100′. A sudden shock or jarring motion to the extended hanger loop 100′ can be absorbed by the extra spring 602, when designed to activate before the moving stop 112 contacts the fixed stop 114. This may be accomplished by using a stiffer coil spring 110, which begins to employ the added extra spring 602 before the moving stop 112 contacts the fixed stop 114.

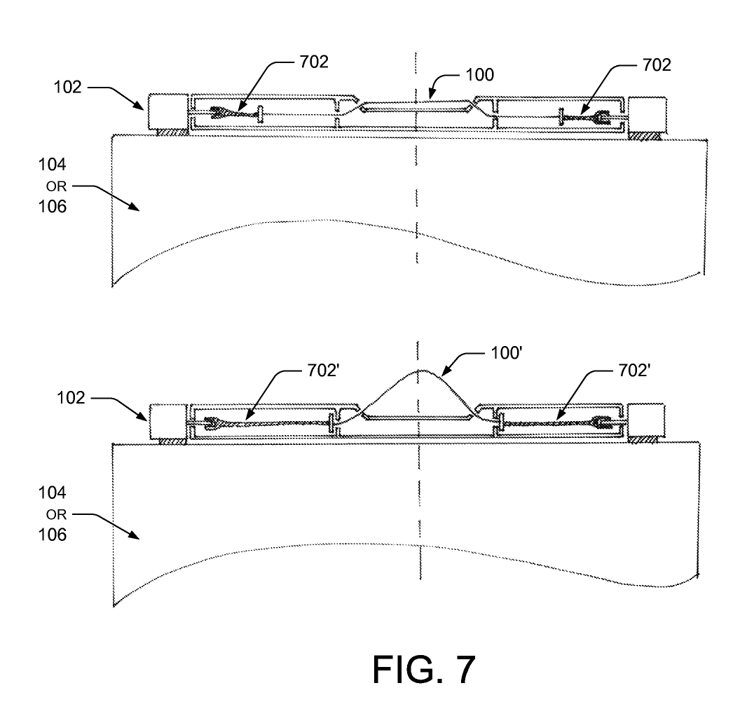

FIG. 7 shows another example implementation, in which an elastic cord or other stretchable member 702 is used for retraction and extension of the extended hanger loop 100′, instead of a spring 110. The stretchable member 702 may be made from a rubberized material, including natural rubber, latex rubber, vulcanized rubber, and so forth, or a stretchable and retractable polymer or elastic.

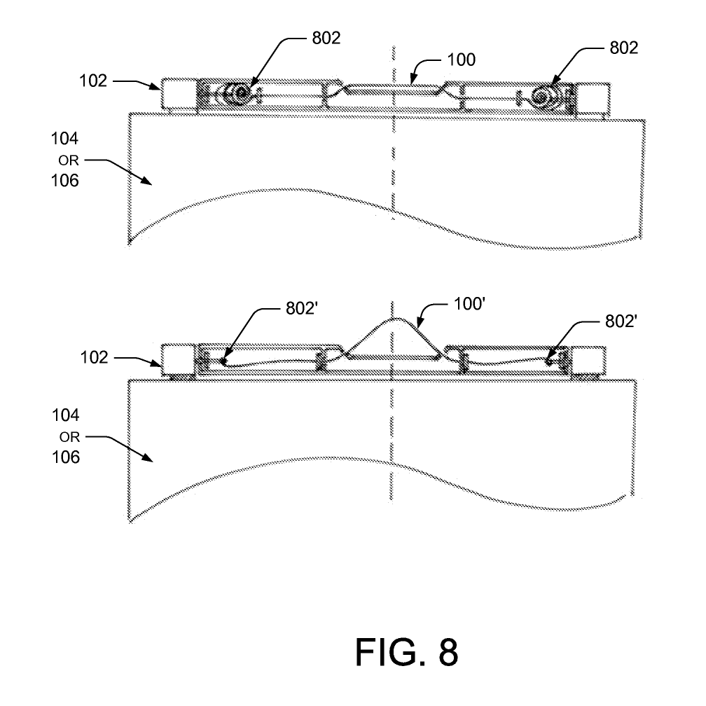

FIG. 8 shows another example implementation, in which one or more spiral torsion springs 802 provides retraction and extension of the metal cord 108 to form the extended hanger loop 100′. Other retraction mechanisms may also be used, including a memory material, memory metal, or one or more leaf springs, cantilever springs, volute springs, gas cylinder springs, and so forth.

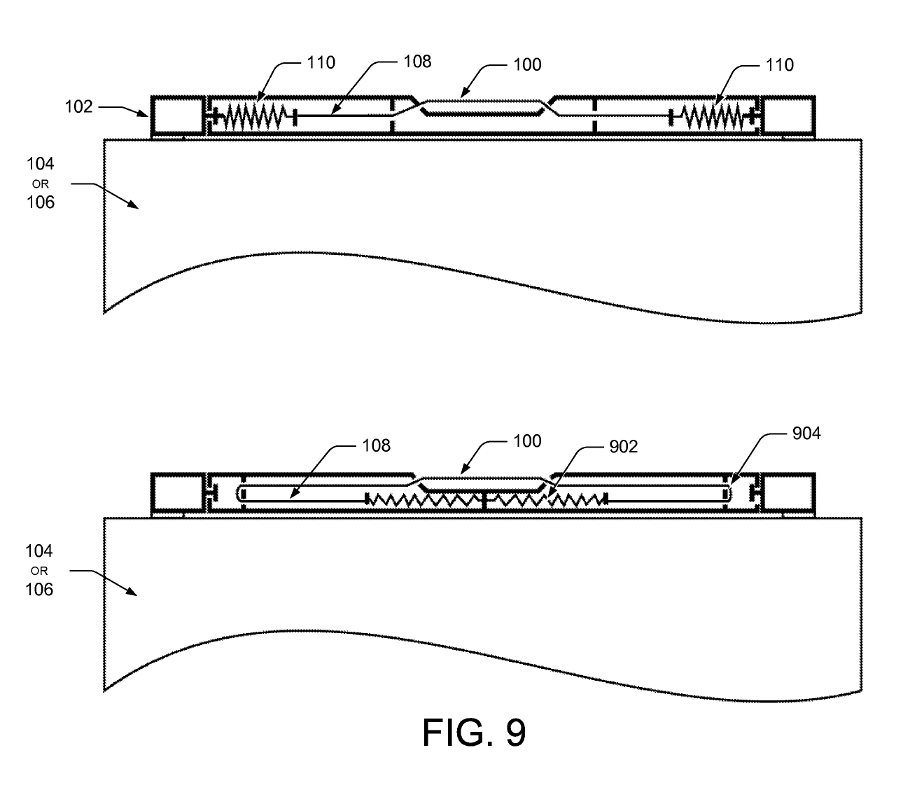

FIG. 9 shows example spring configurations for providing cord retraction. In an implementation, a central spring 902 is attached at each end to the cord 108, which is looped around end pulleys 904 to provide cord tension to the loop of cord 108. For comparison, in another implementation springs 110 are attached at each end of the cord 108 to provide cord tension, as shown in previous Figs.

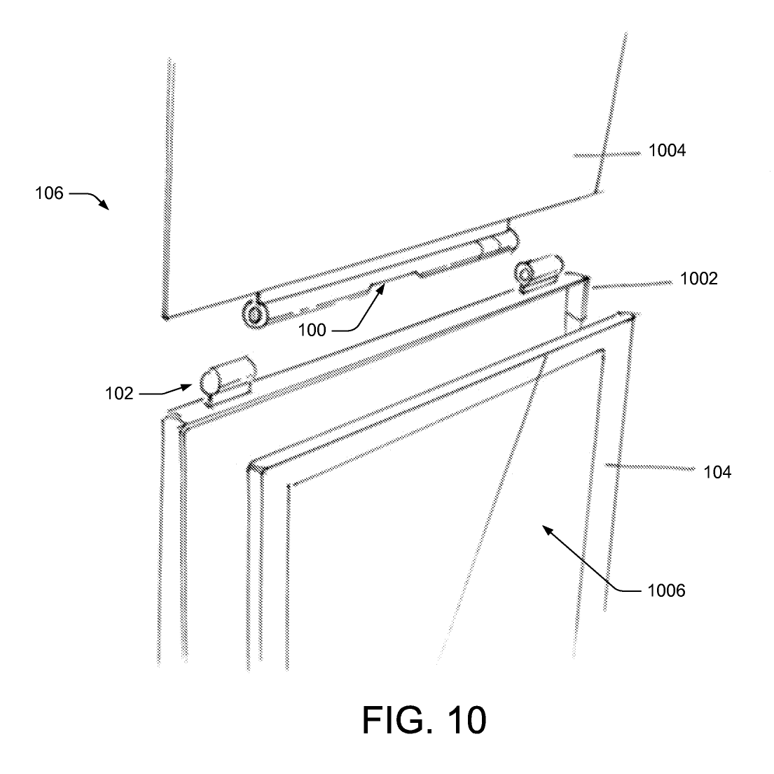

FIG. 10 shows an example built-in retractable hanger 100 as implemented in a hinge 102 on a protective case 106 for a mobile device 104. The protective case 106 may include a back member 1002 that secures and protects the mobile device 104, and a front cover 1004 that covers and protects a screen 1006 of the mobile device 104. The protective case 106 can be constructed of hard shell or flexible plastic polymer, aluminum, or a metal alloy, for example. The protective case 106 can be made in any size to fit and secure the particular mobile device 104.

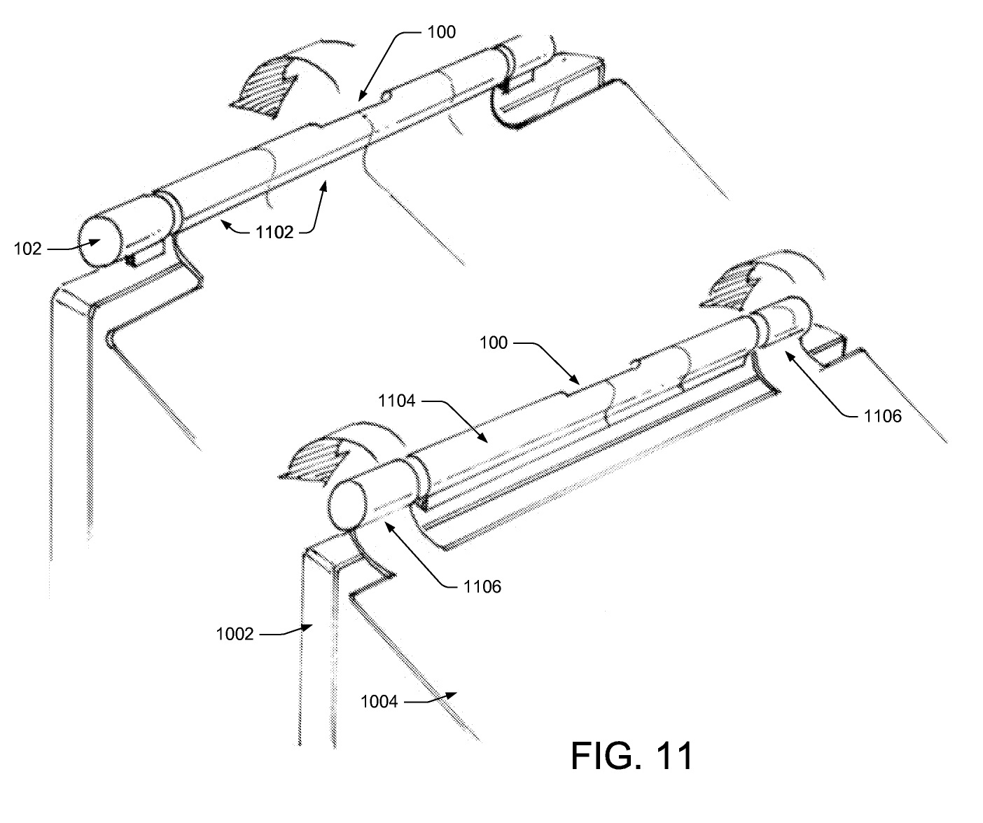

FIG. 11 shows an example built-in retractable hanger 100 as built-into hinges 102 & 102′ on protective cases 106 & 106′ for a mobile device 104. The example built-in retractable hanger 100 can be built into a central segment 1102 of a hinge 102 in which the central segment 1102 bears the load between the back member 1002 of the protective case 106 and the front cover 1004 of the protective case 106. Or, the example built-in retractable hanger 100 can be built into the in-between segment 1104 of a hinge 102 in which the outer segments 1106 of the hinge 102 bear the load between the back member 1002 of the protective case 106 and the front cover 1004 of the protective case 106.

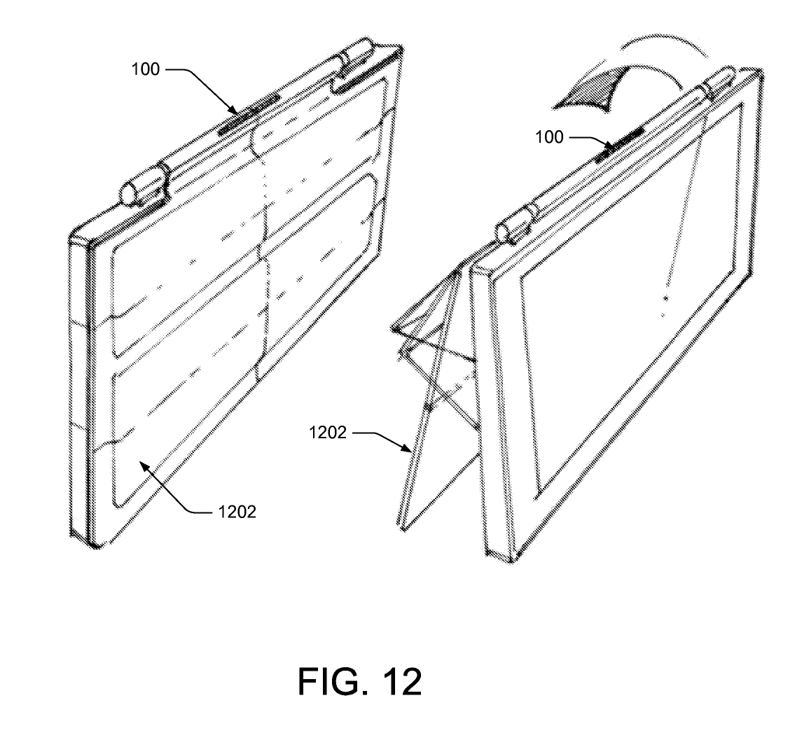

FIG. 12 shows an example implementation of the built-in retractable hanger 100 for a mobile device 104, in combination with a folding front cover 1202 of the mobile device 104 or a folding front cover 1202 of a protective case 106. The folding front cover 1202 flips around to the back of the device 104 or the protective case 106 and folds to become a stand, such as a spacer between a vertical surface (e.g., a seatback) and the back of the device 104 or back member 1002 of the protective case. The combination of these two features, the retractable hanger 100 and the folding front cover 1202 that becomes a stand or a spacer, enables the user to customize the viewing angle of the mobile device 104 when suspending the device 104 from a hanging point 200.

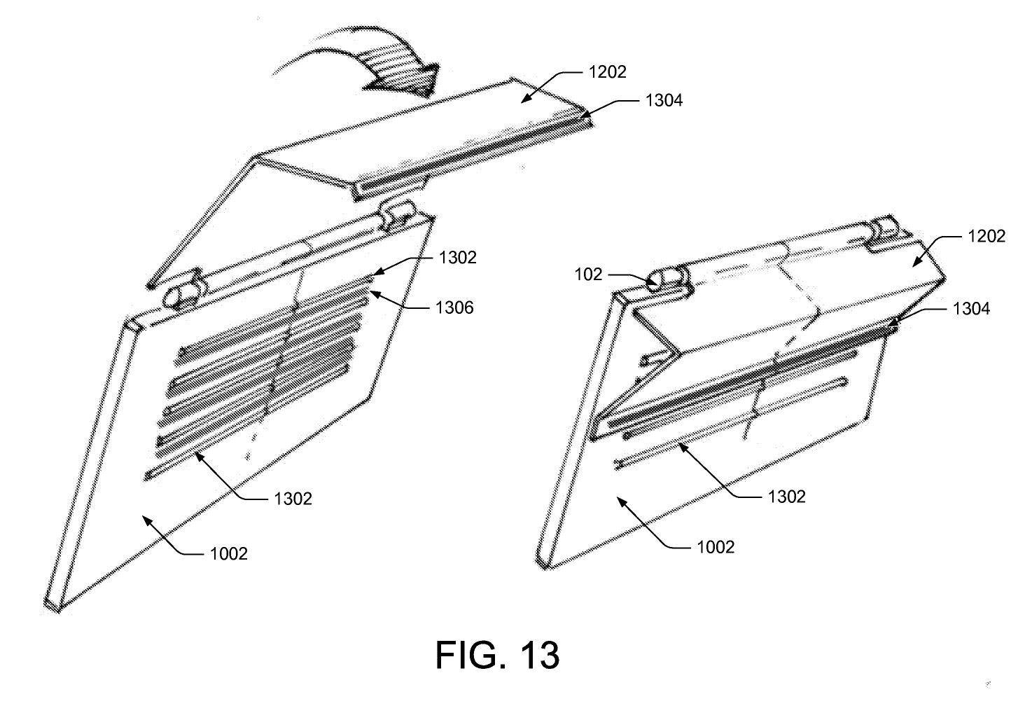

As shown in FIG. 13, the back member 1002 of the protective case 106 (or mobile device 104) may have horizontal ribs 1302 or corrugations to hold an edge of the front cover 1202 that has been flipped over to the rear to become a support or stand in the back of the device 104 for providing viewing angle increments when suspended by the extended hanger loop 100′ from a hanging point 200. A magnet 1304 and metal strip 1306 system secures the edge of the front cover 1202 at specific horizontal ribs 1302. In an implementation, each horizontal rib 1302 has an accompanying metal strip 1306. The magnet 1304 on the edge of the front cover 1202 grabs onto one of the metal strips 1306 by a rib 1302 to secure the folded front cover 1202 at that viewing angle. The magnet 1304 and metal strip 1306 system also provides easy alignment of the folded front cover 1202 when acting as a rear stand.

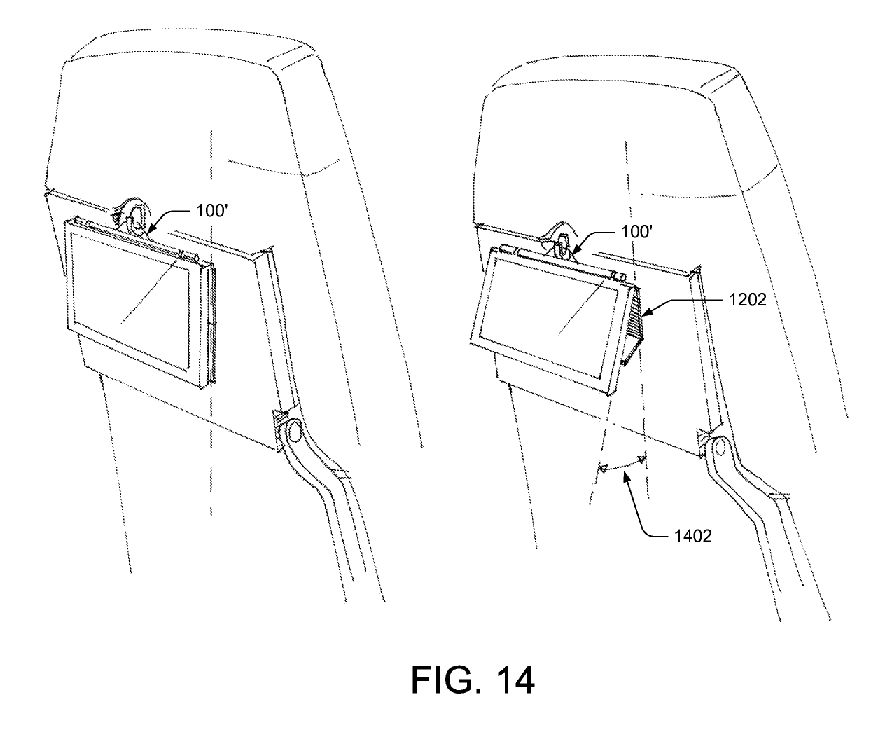

FIG. 14 shows the mobile device 104 or protective case 106 containing the mobile device 104 hung by the extended hanger loop 100′. The folded front cover 1202 folds into a stand in back that changes the viewing angle 1402 of the mobile device when suspended.

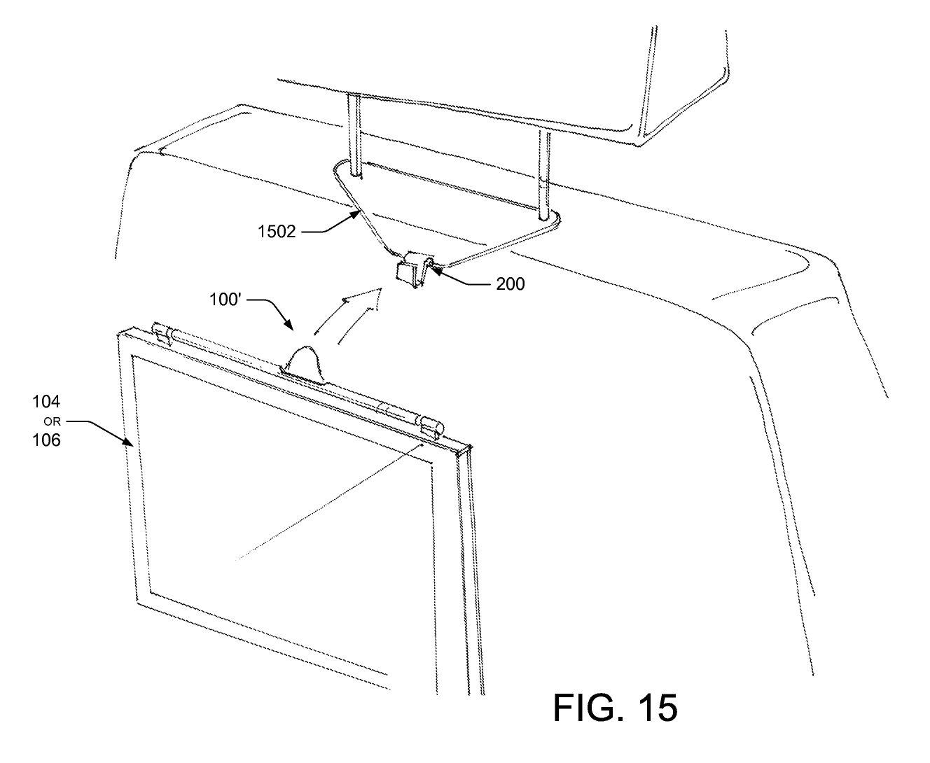

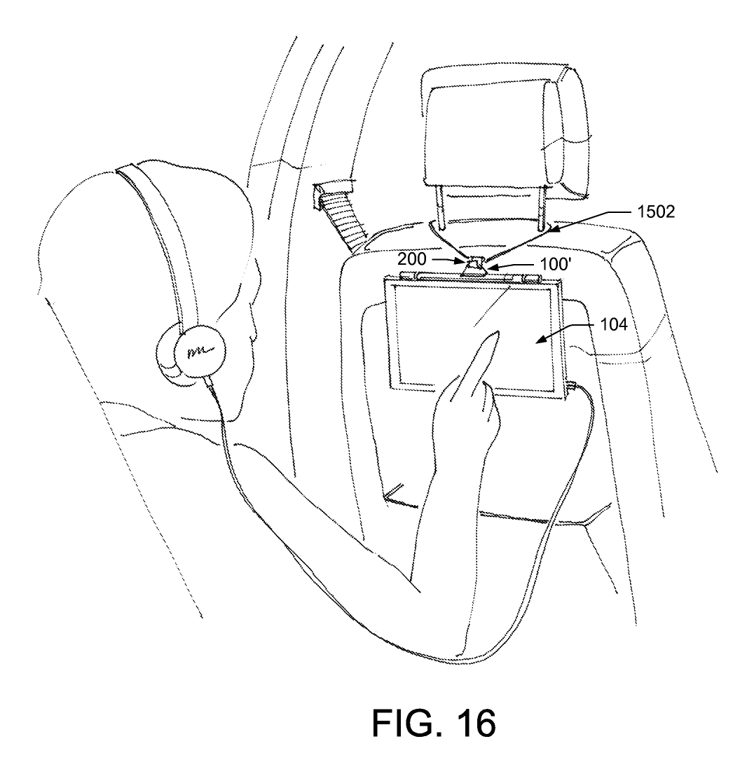

FIG. 15 shows an example anchor accessory 1502 providing a portable hanging point 200 when no hanging point 200 is available for the extended hanger loop 100′. By means of a clasp or a stretchable cord, the anchor accessory 1502 can be secured to an existing feature in the user's space, to provide a temporary hanging point 200. FIG. 16 shows the anchor accessory 1502 in place around a headrest and providing a hanging point 200 for a mobile device 104.

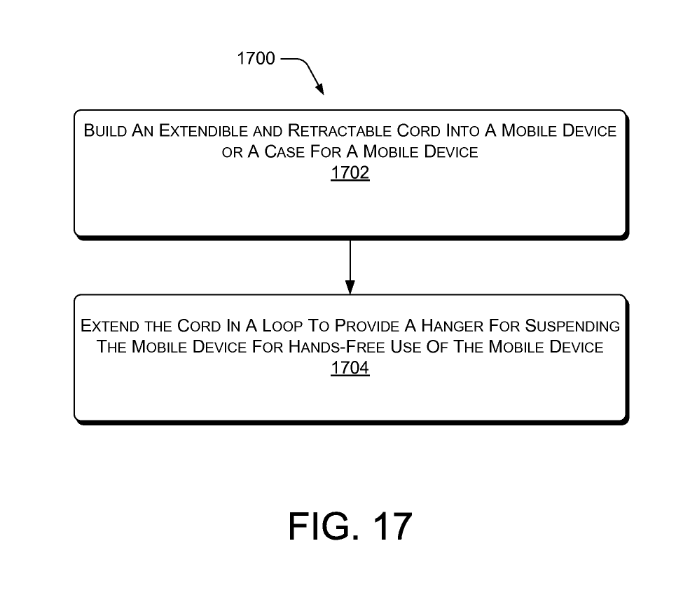

FIG. 17 shows an example method of suspending a mobile device for hands-free use in a travel environment. The operations are shown as individual blocks.

At block 1702, an extendible and retractable cord is built into a mobile device or a case for a mobile device.

At block 1704, the cord is extended in a loop to provide a hanger for suspending the mobile device for hands-free use of the mobile device.

### CONCLUSION

Although only a few example embodiments have been described in detail above, those skilled in the art will readily appreciate that many modifications are possible in the example embodiments without materially departing from the subject matter. Accordingly, all such modifications are intended to be included within the scope of this disclosure as defined in the following claims.

1. An apparatus, comprising:
a cord extendible and retractable within a hinge of a mobile device;
a biasing member connected to at least one end of the cord for maintaining a tension on the cord; and
a hinge to contain the cord, the hinge having an opening for enabling the cord to extend into a loop for suspending the mobile device for hands-free use.

2. The apparatus of claim 1, wherein the cord comprises one of a strong polymer or a metal.

3. The apparatus of claim 1, wherein the mobile device comprises one of a personal computer, a laptop computer, a tablet, an all-in-one (AIO) device, a display, a phone, or a protective case for the mobile device.

4. The apparatus of claim 1, wherein the biasing member comprises one of a folding spring, a coil spring, a helical spring, a spiral torsion spring, an elastic member, a rubberized member, a memory material, a memory metal, a leaf spring, a cantilever spring, a volute spring, or a gas cylinder spring.

5. A mobile device, comprising:
a cord retractably concealed within the mobile device;
a means for pulling the cord into a hanger loop for suspending the mobile device; and
a mechanism for retracting the hanger loop for concealment within the mobile device.

6. The mobile device of claim 5, further comprising a protective case for the mobile device.

7. The mobile device of claim 5, wherein the cord is retractably concealed within a hinge of the mobile device.

8. The mobile device of claim 5, further comprising a front cover of the mobile device; and
wherein the front cover folds back to become a stand for selecting a viewing angle of the mobile device when the mobile device is suspended from the hanger loop.

9. The mobile device of claim 8, further comprising ribs or corrugations on a back member of the mobile device or on a back member of the protective case for the mobile device for providing viewing angle increments when the mobile device is suspended by the hanger loop for hands-free use.

10. The mobile device of claim 9, further comprising at least one magnet in the front cover and at least one metal strip on the back member, wherein the magnet grabs the metal strip to secure the front cover to support a viewing angle and facilitate an alignment of the front cover near one of the ribs.

11. The mobile device of claim 5, wherein the mechanism comprises one of a folding spring, a coil spring, a helical spring, a spiral torsion spring, an elastic member, a rubberized member, a memory material, a memory metal, a leaf spring, a cantilever spring, a volute spring, or a gas cylinder spring.

12. The mobile device of claim 5, wherein the mechanism comprises a central spring, each end of the central spring attached to a loop of the cord, the loop wrapped around pulleys to provide a retraction tension.

13. The mobile device of claim 12, further comprising an additional biasing spring to provide an axial tension on the cord to absorb shocks and jarring motions on the hanger loop.

14. The mobile device of claim 5, further comprising an instance of the cord on at least two sides of the mobile device for suspending the mobile device in a portrait orientation or a landscape orientation.

15. The mobile device of claim 5, further comprising an anchor accessory including a hanging hook on a flexible member to wrap around a fixture for providing a hanging point for the mobile device.

16. The mobile device of claim 5, wherein the hanger loop suspends the mobile device for hands-free use from an airplane tray release handle when the airplane tray is open and when the airplane tray is closed.

17. A method, comprising:
building an extendible and retractable cord into a mobile device or a protective case for a mobile device; and
extending the cord in a loop to provide a hanger for suspending the mobile device for hands-free use of the mobile device.

18. The method of claim 17, further comprising retracting the loop back into the mobile device.
